(19) United States
(12) Patent Application Publication
(10) Pub. No.: US 2024/0397649 A1
(43) Pub. Date: Nov. 28, 2024

(54) FOLDABLE DEVICE

(71) Applicant: Honor Device Co., Ltd., Shenzhen (CN)

(72) Inventor: Bin YAN, Shenzhen (CN)

(21) Appl. No.: 18/257,152

(22) PCT Filed: Dec. 15, 2022
(86) PCT No.: PCT/CN2022/139347

§ 371 Date: Jun. 13, 2023

(30) Foreign Application Priority Data
Mar. 14, 2022 (CN) 202210277265.0

(51) Int. Cl. H05K 5/02; H01Q 1/22

(52) U.S. Cl. CPC H05K 5/0226; H01Q 1/22

(57) ABSTRACT

A provided foldable device includes a body and a flexible display. The body includes a first body portion, a second body portion, and a third body portion that are sequentially disposed, and the first body portion and the third body portion are respectively rotatably connected to two sides in a width direction of the second body portion. The flexible display includes a first screen portion, a first bent-screen portion, a second screen portion, a second bent-screen portion, and a third screen portion that are sequentially connected. The three screen portions are respectively attached to front faces of the three body portions. The first body portion can be folded to overlap the second body portion, and the third body portion can be folded to overlap the folded first body portion

### CROSS-REFERENCE TO RELATED APPLICATIONS

This application claims priority to Chinese Patent Application No. 202210277265.0, filed with the China National Intellectual Property Administration on Mar. 14, 2022 and entitled “FOLDABLE DEVICE”, which is incorporated herein by reference in its entirety.

### TECHNICAL FIELD

This application relates to the field of foldable devices, and in particular, to a foldable device.

### BACKGROUND

A known trifold device usually has an inward and outward folding design. To be specific, the foldable device has two folds, including one inward fold (an inward fold of a screen) and one outward fold (an outward fold of the screen).

However, in a foldable device using an inward and outward folding solution, there is a problem that a rotating shaft structure is complex, and a flexible display needs to meet both inward and outward folding requirements.

### SUMMARY

This application provides a foldable device, to resolve a problem that in a foldable device folded inward and outward, a rotating shaft structure is complex, and a flexible display needs to meet both inward and outward folding requirements.

According to a first aspect, an embodiment of this application provides a foldable device, including a body and a flexible display. The body includes a first body portion, a second body portion, and a third body portion that are sequentially disposed, and the first body portion and the third body portion are respectively rotatably connected to two sides in a width direction of the second body portion: the flexible display includes a first screen portion, a first bent-screen portion, a second screen portion, a second bent-screen portion, and a third screen portion that are sequentially connected, the first screen portion is attached to a front face of the first body portion, the second screen portion is attached to a front face of the second body portion, and the third screen portion is attached to a front face of the third body portion: the first body portion is capable of being folded to overlap the second body portion, so that the first screen portion and the second screen portion are opposite to each other and sandwiched between the front face of the first body portion and the front face of the second body portion; and the third body portion is capable of being folded to overlap the folded first body portion, so that the third screen portion is sandwiched between a rear face of the first body portion and the front face of the third body portion; and a thickness of a side that is of the first body portion and that is connected to the second body portion is large, and a thickness of a side that is of the first body portion and that is away from the second body portion is small.

In the foldable device in this embodiment of this application, an inward folding manner is used between the first body portion and the second body portion and between the third body portion and the second body portion, the thickness of the side that is of the first body portion and that is close to the second body portion is large, and the thickness of the side that is of the first body portion and that is away from the second body portion is small, so that design difficulty of a rotatable connection structure between the first body portion and the second body portion is reduced, and space existing between the second body portion and the third body portion after the second body portion and the third body portion rotate is fully used to help reduce an overall thickness of the foldable device. In addition, in the structure, the flexible display is sandwiched between inner sides of the body portions and is difficult to damage, the flexible display only needs to meet an inward folding requirement, and a requirement on performance of the flexible display is low.

In a possible implementation, the first body portion is in a wedge shape whose thickness gradually changes in a width direction.

In this implementation, the first body portion is in the wedge shape, and has an aesthetic appearance after being unfolded. When the first body portion is folded, the space between the second body portion and the third body portion can be fully used, to help reduce a total thickness of the folded foldable device and the design difficulty of the rotatable connection structure between the first body portion and the second body portion.

In a possible implementation, an included angle between the front face and the rear face of the first body portion ranges from 0.5° to 2°.

In this implementation, the included angle is set to range from 0.5° to 2°, so that the thickness of the first body portion gradually changes, without exerting too large impact on the appearance of the first body portion.

In a possible implementation, the thickness of the side that is of the first body portion and that is connected to the second body portion ranges from 4 mm to 8 mm, the thickness of the side that is of the first body portion and that is away from the second body portion ranges from 2 mm to 5 mm, an included angle between the front face and the rear face of the first body portion ranges from 0.5° to 2°: a thickness of the second body portion ranges from 4 mm to 8 mm, and the front face and a rear face of the second body portion are parallel to each other; and a thickness of a side that is of the third body portion and that is connected to the second body portion ranges from 5 mm to 8 mm, a thickness of a side that is of the third body portion and that is away from the second body portion ranges from 2 mm to 8 mm, and an included angle between the front face and a rear face of the first body portion ranges from 0° to 2°.

In this implementation, a proper size is set, to obtain a foldable device with a small thickness.

In a possible implementation, the third body portion is in a wedge shape whose thickness gradually changes in a width direction, a thickness of a side that is of the third body portion and that is connected to the second body portion is large, and a thickness of a side that is of the third body portion and that is away from the second body portion is small; and an included angle between the front face and a rear face of the third body portion is equal to an included angle between the front face and the rear face of the first body portion.

In this implementation, after the first body portion is folded to overlap the second body portion and the third body portion is folded to overlap the first body portion, the rear face of the first body portion and the front face of the third body portion are fitted after overlapping, and the thickness of the first body portion and a thickness of the third body portion are in a complementary state, so that an overall thickness of the first body portion and the third body portion are kept basically constant, the folded foldable device is in a common state in which a front face and a rear face (that is, a rear face of a second housing and a rear face of a third housing) are parallel to each other, and an appearance of an electronic device conforms to a habit of a consumer. Certainly, in this embodiment, “parallel” does not need to be “completely parallel”. Instead, an included angle that is slightly greater than 0° and that is caused due to impact exerted by shape and position tolerances within a specific range is allowed, for example, an included angle within a range from 0 to 1°.

In a possible implementation, the front face and a rear face of the third body portion are parallel.

In this implementation, the thickness of the side that is of the third body portion and that is away from the second body portion can be set to be large. Although the front face and the rear face of the folded foldable device are not parallel to each other, it is convenient to dispose a side button (for example, a power button or a volume button) and dispose more structures inside the third body portion. In addition, when an included angle between the front face and the rear face of the folded foldable device is not large (for example, less than) 5°, little impact is exerted on an overall appearance and use experience of the device.

In a possible implementation, a button structure is disposed on a side of that is the third body portion and that is away from the second body portion.

In this implementation, the side of that is the third body portion and that is away from the second body portion is exposed, to help dispose and operate the button structure.

In a possible implementation, the first body portion includes a wedge-shaped portion whose thickness gradually changes in a width direction and an equal-thickness portion that has a constant thickness and that is connected to one or two sides in a width direction of the wedge-shaped portion.

In this implementation, the first body portion is partially in a wedge shape, partially has an equal thickness, and has different shapes.

In a possible implementation, a wedge angle of the wedge-shaped portion ranges from 0.5° to 1.8°.

This implementation provides the range of the wedge angle of the first body portion that is in the wedge shape and that partially has an equal thickness.

In a possible implementation, in a state in which the first body portion is folded to overlap the second body portion, the first screen portion and the second screen portion overlap each other, and the first bent-screen portion is bent into a water drop shape; and in a state in which the third body portion is folded to overlap the folded first body portion, the third screen portion overlaps the rear face of the first body portion, and the second bent-screen portion is bent into a U shape.

In this implementation, based on the wedge-shaped design of the first body portion, the second screen portion and the third screen portion need to rotate by a degree less than 180° to change from an unfolded state to a folded state. Compared with a common solution of rotating by 180°, a requirement on folding performance of the flexible display is lowered.

In a possible implementation, in the state in which the first body portion is folded to overlap the second body portion, the first screen portion and the second screen portion are fitted or at a distance less than 1.0 mm, the first bent-screen portion bent into the water drop shape includes an arc section, a first transition section, and a second transition section, the first transition section is transitionally connected between the arc section and the first screen portion, and the second transition section is transitionally connected between the arc section and the second screen portion.

In this implementation, in a water-drop-shaped bend solution of the flexible display, screens have a small distance from each other or are even directly fitted, to reduce a total thickness of a folded structure. However, to realize the water-drop-shaped bend solution, there is a high requirement on thicknesses of body portions (rotatable connection positions of the first body portion and the second body portion in this embodiment) on two sides of a water-drop-shaped bend, and this is inconducive to control of the total thickness existing after folding. In a U-shaped bend solution of the flexible display, there is a large distance after folding, and control of the total thickness existing after folding is limited. In this embodiment, the first body portion is arranged in a wedge shape, to skillfully implement a design that a thickness of a side that is of the first body portion and that is close to a water-drop-shaped bend is large (which helps meet a requirement on a thickness of the first body portion at a connection point in the water-drop-shaped bend solution), and a thickness of a side that is of the first body portion and that is close to a U-shaped bend is small (a required distance at the U-shaped bend is reduced, and space within a range of the distance is fully used). A structure is very compact, so that the thickness of the folded foldable device can be greatly reduced compared with that in the conventional technology.

In a possible implementation, the first body portion and the second body portion are rotatably connected by using a first rotation structure; and the third body portion and the second body portion are rotatably connected by using a second rotation structure.

In this implementation, the first rotation structure and the second rotation structure are used to implement a rotatable connection of adjacent body portions.

In a possible implementation, the first rotation structure and/or the second rotation structure are/is a hinge structure.

In this implementation, the hinge structure is used to better implement the rotatable connection of adjacent body portions.

In a possible implementation, the foldable device further includes a first support structure and a second support structure, the first support structure is configured to support the first bent-screen portion, and the second support structure is configured to support the second bent-screen portion.

In this implementation, the first support structure and the second support structure can support the first bent-screen portion and the second bent-screen portion, so that the water-drop-shaped bend or U-shaped bend of the flexible display is realized, and the flexible display is entirely on one plane when being unfolded.

In a possible implementation, the first support structure includes a first support plate, a second support plate, and a third support plate: the first support plate is rotatably connected to the first body portion, the second support plate is rotatably connected to the second body portion, and the third support plate is fixedly connected to the first rotation structure: in a state in which the first body portion and the second body portion are relatively unfolded, the first support plate and the second support plate are respectively located on two sides of the third support plate, and support faces of the first support plate, the second support plate, and the third support plate are on a same plane to jointly support the first bent-screen portion; and in a state in which the first body portion and the second body portion are folded to overlap each other, the first bent-screen portion is in a water drop shape, the first support plate rotates to a state of being parallel to the first transition section and supports the first transition section from below, the second support plate rotates to a state of being parallel to the second transition section and supports the second transition section from below, and the third support plate supports the arc section from below.

In this implementation, the first support plate, the second support plate, and the third support plate can reliably support the second bent-screen portion in both the folded state and the unfolded state of the foldable device.

In a possible implementation, the second support structure includes a fourth support plate and a fifth support plate: the fourth support plate is fixedly connected to a side that is of the second body portion and that is close to the third body portion, and the fifth support plate is fixedly connected to a side that is of the third body portion and that is close to the second body portion: in a state in which the third body portion and the second body portion are relatively unfolded, support faces of the fourth support plate and the fifth support plate are on a same plane to jointly support the second bent-screen portion; and in a state in which the third body portion and the second body portion are relatively folded into a folded state, the fourth support plate synchronously rotates along with the second body portion to provide support near a junction of the second screen portion and the second bent-screen portion, and the fifth support plate synchronously rotates along with the third body portion to provide support near a junction of the third screen portion and the second bent-screen portion.

In this implementation, the fourth support plate and the fifth support plate can reliably support the second bent-screen portion in both the folded state and the unfolded state of the foldable device.

In a possible implementation, a secondary display is further disposed on a rear face of the third body portion, and a protective glass plate is disposed on an outer side of the secondary display.

In this implementation, the secondary display is disposed, so that the folded foldable device has a display function.

In a possible implementation, a front-facing camera is disposed on the rear face of the third body portion, and the front-facing camera penetrates the secondary display or is located on an inner side of the secondary display.

In this implementation, the secondary display disposed on the rear face of the third body portion can implement display in the folded state.

In a possible implementation, the foldable device further includes a rear-facing camera and/or a main battery, and the rear-facing camera and/or the main battery are/is disposed on the second body portion.

In this implementation, the second body portion has a regular size and a large thickness, to help dispose a camera assembly of a proper size.

In a possible implementation, the foldable device includes a flexible-display lead-out wire and an antenna; and the flexible-display lead-out wire is led out from a thinner side that is of the flexible display and that corresponds to the first body portion, and the antenna is disposed on a side that is of the third body portion and that is away from the second body portion.

In this implementation, the first body portion is sandwiched between the second body portion and the third body portion, and it is not suitable to dispose a folded-state antenna on an edge of the first body portion. Therefore, the flexible-display lead-out wire is led out from an edge of the first body portion, the side that is of the third body portion and that is away from the second body portion is not shielded, and disposing the antenna on the side is not prone to affecting antenna signal quality.

In a possible implementation, the first body portion includes a first-body-portion body and a first side housing connected to the first-body-portion body, the second body portion includes a second-body-portion body and a second side housing connected to the second-body-portion body, the third body portion includes a third-body-portion body and a third side housing connected to the third-body-portion body, and the flexible display includes a display area and an outer edge area located on a periphery of the display area: the flexible display is laid on front faces of the first-body-portion body, the second-body-portion body, and the third-body-portion body; and the first side housing, the second side housing, and the third side housing jointly form an outer side-housing frame around a periphery of the body, the outer edge area is sandwiched between the outer side-housing frame and each of the first-body-portion body, the second-body-portion body, and the third-body-portion body, and a width-direction gap exists between one or two sides of the outer side-housing frame in a width direction of the foldable device and a corresponding side of the flexible display, to allow the flexible display to displace relative to a width direction of the body when the foldable device changes between different folding states.

In this implementation, in a structural arrangement of a body portion, a displacement existing in a width direction when the flexible display is bent can be allowed. In addition, the first side housing, the second side housing, and the third side housing protrude from an outer surface of the flexible display, and the side housings abut against each other after folding, to prevent the flexible display from being in contact with an opposite-side structure, and reduce a friction and damage possibility.

In a possible implementation, a notch is disposed in each of a position that is in the outer side-housing frame and that corresponds to a rotatable connection point between the first body portion and the second body portion and a position that is in the outer side-housing frame and that corresponds to a rotatable connection point between the third body portion and the second body portion.

In this implementation, the notch is disposed, to avoid bending abutment between the first side housing and the second side housing and between the second side housing and the third side housing.

In a possible implementation, a part that is of the rear face of the first body portion and that is located on a side that is of the first body portion and that is away from the second body portion is recessed in a thickness direction of the first body portion, to form avoidance space, so that the first body portion is in a step shape in which a thickness of a part corresponding to the avoidance space is small and a thickness of a part outside the avoidance space is large; and the third body portion is accommodated in the avoidance space when overlapping the first body portion.

In this implementation, the first body portion is arranged in the step shape, so that the side that is of the first body portion and that is close to the second body portion is thick, and the side that is of the first body portion and that is away from the second body portion is thin, to help reduce the overall thickness.

### BRIEF DESCRIPTION OF DRAWINGS

To describe the technical solutions in embodiments of this application more clearly, the following briefly describes the accompanying drawings in the embodiments. It should be understood that, the accompanying drawings below only show some embodiments of this application, and thus should not be considered as limitations on the scope. A person of ordinary skill in the art may still derive other related drawings from the accompanying drawings without creative efforts.

FIG. 1 is a schematic diagram of a structure in a first implementation of a foldable device according to an embodiment of this application, where the foldable device is in an unfolded state;

FIG. 2 is a top view of the foldable device in FIG. 1;

FIG. 3 is a schematic diagram of a structure existing when the foldable device in FIG. 1 is folded into a folded state:

FIG. 4 is a top view of the foldable device in FIG. 3;

FIG. 5 is a schematic diagram of a structure existing when the foldable device in FIG. 1 is folded into an intermediate state:

FIG. 6 is a schematic diagram of a structure in a second implementation of a foldable device according to an embodiment of this application, where the foldable device is in a folded state:

FIG. 7 is a schematic diagram of a structure in a third implementation of a foldable device according to an embodiment of this application, where the foldable device is in a folded state:

FIG. 8 is a schematic diagram of a structure in a fourth implementation of a foldable device according to an embodiment of this application, where the foldable device is in a folded state:

FIG. 9 is a schematic diagram of a structure existing when the foldable device in FIG. 8 is unfolded:

FIG. 10 is an enlarged view of a position A in FIG. 9;

FIG. 11 is an enlarged view of a position B in FIG. 9:

FIG. 12 is a schematic diagram of a structure in a fifth implementation of a foldable device according to an embodiment of this application, where the foldable device is in a folded state:

FIG. 13 is a top view of the foldable device in FIG. 12, where the foldable device is in an unfolded state;

FIG. 14 is a schematic diagram of a structure in a sixth implementation of a foldable device according to an embodiment of this application, where the foldable device is in a folded state; and

FIG. 15 is a schematic diagram of a structure in a seventh implementation of a foldable device according to an embodiment of this application, where the foldable device is in a folded state.

### DESCRIPTION OF REFERENCE NUMERALS OF MAIN ELEMENTS

Foldable device 10
Body 11
Flexible display 12
First screen portion 12a
Second screen portion 12b
Third screen portion 12c
First bent-screen portion 12d
Second bent-screen portion 12e
Display area 12f
Outer edge area 12g
First transition section d1
Second transition section d2
Arc section d3
First body portion 13
First-body-portion body 13a
First side housing 13b
Wedge-shaped portion 131
Equal-thickness portion 132
Second body portion 14
Second-body-portion body 14a
Second side housing 14b
Third body portion 15
Third-body-portion body 15a
Third side housing 15b
First rotation structure 16
Second rotation structure 17
First support structure 18
Second support structure 19
First support plate 20
Second support plate 21
Third support plate 22
Fourth support plate 23
Fifth support plate 24
Front-facing camera 25
Secondary display 26
Secondary-display lead-out wire 26a
Protective glass plate 27
Button structure 28
Rear-facing camera 29
Main battery 30
Flexible-display lead-out wire 31
Antenna 32
Driver chip 33
Outer side-housing frame 34
Avoidance space C1
Width-direction gap f1
Through hole K1
Notch K2
Support face P1 and P2
Front face S1
Rear face S2
Width direction Y1
Thickness direction Y2

### DESCRIPTION OF EMBODIMENTS

The following clearly and completely describes the technical solutions in embodiments of this application with reference to the accompanying drawings in the embodiments of this application. It is clear that the described embodiments are only some but not all of the embodiments of this application.

It should be noted that when a component is referred to as being “fastened to” another component, the component may be directly fastened to the another component, or there may be a component between the component and the another component. When a component is considered as being “connected to” another component, the component may be directly connected to the another component, or there may be a component between the component and the another component. When a component is considered as being “disposed on” another component, the component may be directly disposed on the another component, or there may be a component between the component and the another component. The terms “perpendicular”, “horizontal”, “left”, “right”, and other similar expressions as used in this specification are for illustration only.

Unless otherwise defined, meanings of all technical and scientific terms used in this specification are the same as those usually understood by a person skilled in the art to which this application belongs. The terms used herein in the specification of this application are merely intended to describe specific implementations but not intended to limit this application. The term “or/and” used in this specification includes any or all combinations of one or more related listed items.

Some implementations of this application are described in detail. In absence of conflicts, the following implementations and features in the implementations may be combined.

### EMBODIMENT

An embodiment of this application provides some implementations of a foldable device. The foldable device may be a foldable mobile phone, a foldable tablet computer, or another foldable device.

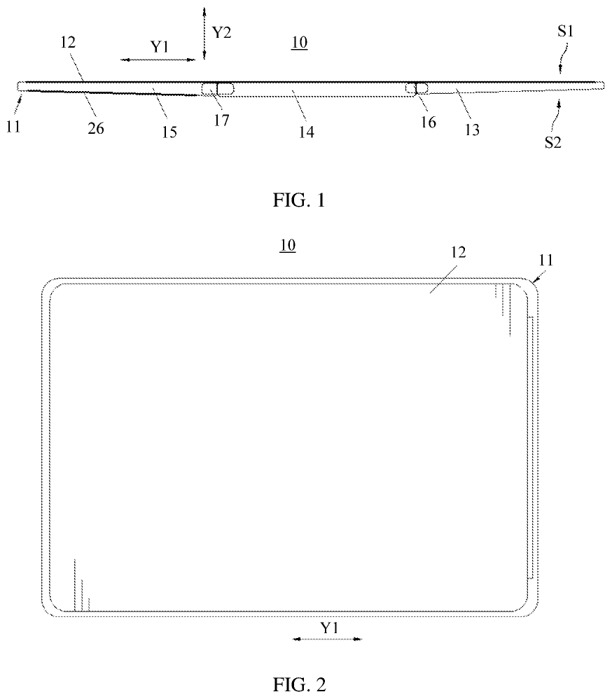

Referring to FIG. 1 to FIG. 5, a foldable device 10 provided in an embodiment of this application includes a body 11 and a flexible display 12.

The body 11 includes a first body portion 13, a second body portion 14, and a third body portion 15 that are sequentially disposed, and the first body portion 13 and the third body portion 15 are respectively rotatably connected to two sides in a width direction Y1 of the second body portion 14. If the foldable device 10 needs to be provided with a mechanical structure or an electronic component such as a housing, a battery, a main board, a camera assembly, a button assembly, or an antenna, the mechanical structure or the electronic component may be properly distributed on the three body portions: the first body portion 13, the second body portion 14, and the third body portion 15 based on a requirement. For example, a structure such as a main battery or a rear-facing camera that occupies large thickness space may be disposed on a body portion (for example, the second body portion 14) with a large thickness, and the button assembly may be disposed in a position that facilitates an operation, such as a side edge of the third body portion 15.

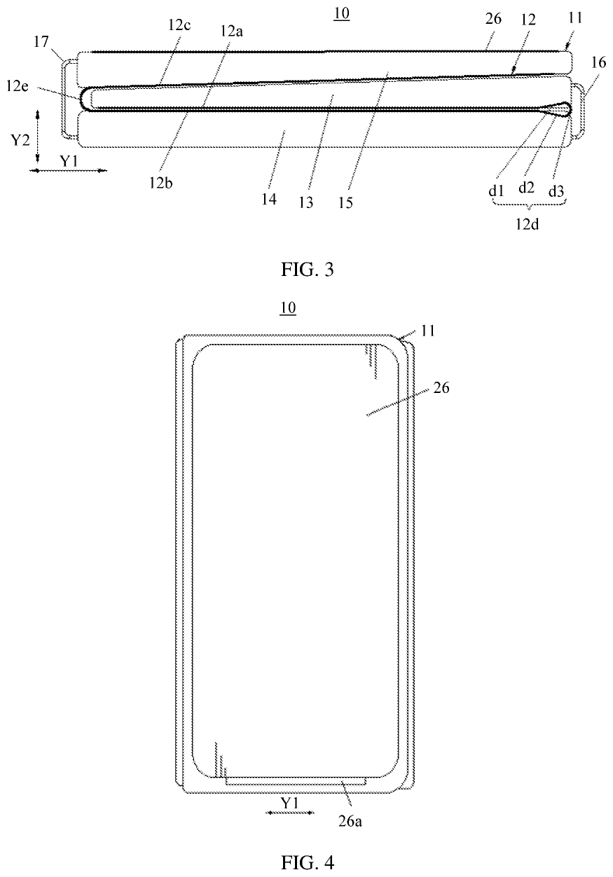

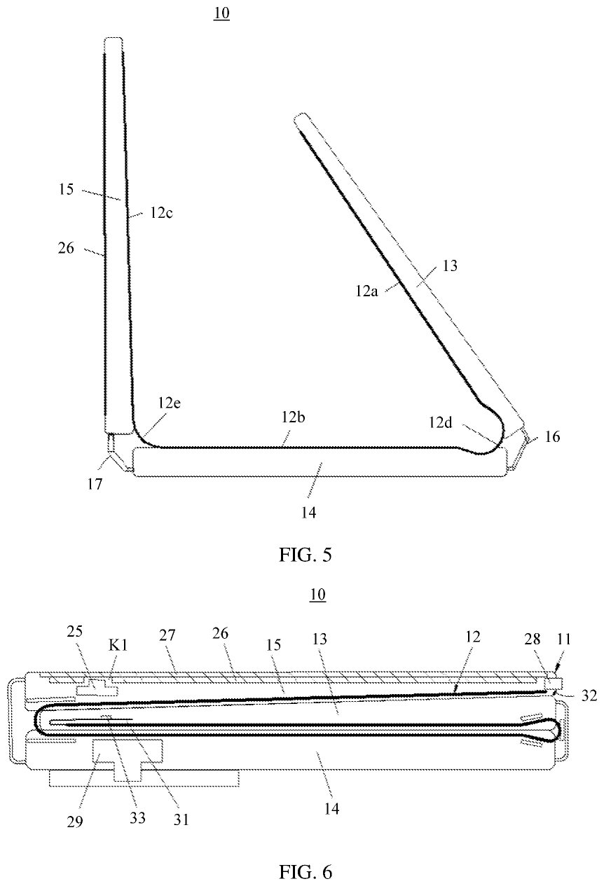

Through relative rotation, the first body portion 13, the second body portion 14, and the third body portion 15 can be rotated into an unfolded state (referring to FIG. 1 and FIG. 2), a folded state (referring to FIG. 3 or FIG. 4), and an intermediate state (referring to FIG. 5) between the folded state and the unfolded state. Usually, the folded state and the unfolded state are two common use states of the foldable device 10. Certainly, some intermediate states may also be designed as common use states.

The flexible display 12 is a foldable flexible structure, and may be of a flexible structure in which the flexible display 12 may be bent in any position, for example, may be an organic light-emitting diode (organic light-emitting diode, OLED) display, an active-matrix organic light-emitting diode or an active-matrix organic light-emitting diode (active-matrix organic light-emitting diode, AMOLED) display, a mini organic light-emitting diode (mini organic light-emitting diode) display, a micro light-emitting diode (micro organic light-emitting diode) display, a micro organic light-emitting diode (micro organic light-emitting diode) display, or a quantum dot light emitting diode (quantum dot light emitting diodes, QLED) display. The flexible display 12 may alternatively be of a structure in which the flexible display 12 may be bent only in some positions but cannot be bent or have a non-bendable design in another position.

In an inward folding manner used in this embodiment, the flexible display 12 is folded on an inner side, and is usually also referred to as an “inner screen”. Correspondingly, a screen facing an outside after being folded is referred to as an “outer screen” (for example, a secondary display 26 described below).

In this embodiment, the flexible display 12 includes a first screen portion 12a, a first bent-screen portion 12d, a second screen portion 12b, a second bent-screen portion 12e, and a third screen portion 12c that are sequentially connected.

The first screen portion 12a is attached to a front face S1 of the first body portion 13, the second screen portion 12b is attached to a front face S1 of the second body portion 14, the third screen portion 12c is attached to a front face S1 of the third body portion 15, the first bent-screen portion 12d approximately corresponds to a rotatable connection point between the first body portion 13 and the second body portion 14, and the second bent-screen portion 12e approximately corresponds to a rotatable connection point between the third body portion 15 and the second body portion 14. Each body portion has a front face S1 and a rear face S2 that are opposite in a thickness direction Y2, one face in which the flexible display 12 is located is defined as the front face S1, and the other face is defined as the rear face S2. “Attach” herein may be an adhesive manner or another connection manner. Certainly, in some embodiments, attachment between the flexible display 12 and a body portion allows the flexible display 12 to have a specific relative displacement relative to the body portion, so as to adapt to misalignment between the flexible display 12 and a body portion when the flexible display 12 is bent. When the misalignment is small and negligible, “attach” may alternatively be a completely fixed mating connection.

In the flexible display 12, the first bent-screen portion 12d and the second bent-screen portion 12e are of a bendable structure, and the first screen portion 12a, the second screen portion 12b, and the third screen portion 12c may be of a bendable structure or may be of a rigid structure. In some implementations, the flexible display 12 is of an integral screen structure, and the first screen portion 12a, the first bent-screen portion 12d, the second screen portion 12b, the second bent-screen portion 12e, and the third screen portion 12c have no significant structural performance difference.

Referring to FIG. 4, the first body portion 13 can be folded to overlap the second body portion 14, so that the first screen portion 12a and the second screen portion 12b are opposite to each other and are sandwiched between the front face S1 of the first body portion 13 and the front face S1 of the second body portion 14. Herein, the first screen portion 12a and the second screen portion 12b may be fully fitted or there may be a small gap (for example, less than 1.0 mm). In actual use, the gap may be 0.9 mm, 0.7 mm, 0.5 mm, or the like. The third body portion 15 can be folded to overlap the folded first body portion 13, so that the third screen portion 12c is sandwiched between a rear face S2 of the first body portion 13 and the front face S1 of the third body portion 15. The third screen portion 12c and the rear face S2 of the first body portion 13 may be fully fitted or there may be a small gap (for example, less than 1.0 mm). A smaller gap leads to a smaller total thickness of the foldable device 10 in a folded state. When the gap is not zero, a scratch possibly caused by contact and friction on an outer surface of the flexible display 12 can be prevented. When the gap is zero, a design may be needed to prevent a surface of the flexible display 12 from being scratched. For example, a wear-resistant surface is used, a structure that prevents body portions from sliding relative to each other in the folded state is used, or another feasible anti-scratching design is used. To limit the gap, a specific protrusion structure (for example, an outer side-housing frame 34 in the following embodiment) protruding from the flexible display 12 may exist between corresponding body portions, and the protrusion structure limits overlapped body portions, to ensure that a controllable gap can exist between the outer surface of the flexible display 12 and an opposite-side structure.

Referring to FIG. 2, FIG. 4, and FIG. 5, a thickness of a side that is of the first body portion 13 and that is connected to the second body portion 14 is large, and a thickness of a side that is of the first body portion 13 and that is away from the second body portion 14 is small.

In the foldable device 10 in this embodiment of this application, an inward folding manner is used between the first body portion 13 and the second body portion 14 and between the third body portion 15 and the second body portion 14, the thickness of the side that is of the first body portion 13 and that is close to the second body portion 14 is large, and the thickness of the side that is of the first body portion 13 and that is away from the second body portion 14 is small, so that design difficulty of a rotatable connection structure between the first body portion 13 and the second body portion 14 is reduced, and space existing between the second body portion 14 and the third body portion 15 after the second body portion 14 and the third body portion 15 rotate is fully used to help reduce an overall thickness of the foldable device 10. In addition, in the structure, the flexible display 12 is sandwiched between inner sides of the body portions and is difficult to damage, the flexible display 12 only needs to meet an inward folding requirement, and a requirement on performance of the flexible display 12 is low.

In an implementation, the first body portion 13 is in a wedge shape whose thickness gradually changes in the width direction Y1. For example, an included angle between the front face S1 and the rear face S2 of the first body portion 13 is set to be from 0.5° to 2°. Certainly, a wedge-shaped portion of the first body portion 13 may extend to only one section in the width direction Y1 of the first body portion 13. In other words, in the width direction Y1 of the first body portion 13, a thickness of a part of the first body portion 13 may be kept constant, and a thickness of the other part of the first body portion 13 gradually changes.

The first body portion 13 is designed to be in the wedge shape, and has an aesthetic appearance after being unfolded. When the first body portion 13 is folded, the space between the second body portion 14 and the third body portion 15 can be fully used, to help reduce a total thickness of the folded foldable device 10 and design difficulty of a rotatable connection structure between the first body portion 13 and the second body portion 14.

In some implementations, a secondary display 26 is further disposed on a rear face S2 of the third body portion 15, so that the folded foldable device 10 has a display function. A secondary-display lead-out wire 26a (referring to FIG. 4) of the secondary display may be led out from a lower side of the secondary display. The secondary display 26 does not need to have a folding function. Therefore, a protective glass plate 27 may be disposed on an outer side of the secondary display 26, to protect the secondary display 26. Certainly, the secondary display 26 may be omitted and is not disposed.

In this embodiment, both the front face S1 and the rear face S2 of the first body portion 13 are planes. In some other embodiments, the front face S1 and the rear face S2 of the first body portion 13 are arc surfaces, but the thickness of the side that is of the first body portion 13 and that is close to the second body portion 14 needs to be kept large and the thickness of the side that is of the first body portion 13 and that is away from the second body portion 14 needs to be kept small.

In an implementation, as shown in FIG. 4 or FIG. 6, to adapt to the arrangement of the wedge shape of the first body portion 13, the third body portion 15 is in a wedge shape whose thickness gradually changes in the width direction Y1, a thickness of a side that is of the third body portion 15 and that is connected to the second body portion 14 is large, and a thickness of a side that is of the third body portion 15 and that is away from the second body portion 14 is small. An included angle between the front face S1 and the rear face S2 of the third body portion 15 is equal to the included angle between the front face S1 and the rear face S2 of the first body portion 13. Therefore, after the first body portion 13 is folded to overlap the second body portion 14 and the third body portion 15 is folded to overlap the first body portion 13, the rear face S2 of the overlapped first body portion 13 and the front face S1 of the third body portion 15 are fitted, and a thickness of the first body portion 13 and a thickness of the third body portion 15 are in a complementary state, to keep an overall thickness of the first body portion 13 and the third body portion 15 to be basically constant, so that the folded foldable device 10 is in a common state in which a front face S1 and a rear face S2 (that is, a rear face S2 of a second housing and a rear face S2 of a third housing) are parallel to each other, and an appearance of an electronic device conforms to a habit of a consumer.

In some other implementations, the front face S1 and the rear face S2 of the third body portion 15 are parallel (as shown in FIG. 7), or the included angle is less than the included angle between the front face S1 and the rear face S2 of the first body portion 13. In this case, the thickness of the side that is of the third body portion 15 and that is away from the second body portion 14 may be set to be large. Although the front face S1 and the rear face S2 of the folded foldable device 10 may be unparallel to each other, it is convenient to dispose a button structure 28 (for example, a power button or a volume button) and dispose more other structures (for example, an in-screen camera) inside the third body portion 15. In addition, when the included angle between the front face S1 and the rear face S2 of the folded foldable device 10 is not large (for example, less than) 2°, little impact is exerted on an overall appearance and use experience of the device.

Based on the foregoing implementations, a size of a body portion in this embodiment may be designed as follows: The thickness of the side that is of the first body portion 13 and that is connected to the second body portion 14 ranges from 4 mm and 8 mm, the thickness of the side that is of the first body portion 13 and that is away from the second body portion 14 ranges from 2 mm to 5 mm, and the included angle between the front face S1 and the rear face S2 of the first body portion 13 ranges from 0.5° to 2°; a thickness of the second body portion 14 ranges from 4 mm to 8 mm, and the front face S1 and the rear face S2 of the second body portion 14 are parallel to each other: the thickness of the side that is of the third body portion 15 and that is connected to the second body portion 14 ranges from 5 mm to 8 mm, the thickness of the side that is of the third body portion 15 and that is away from the second body portion 14 ranges from 2 mm to 8 mm, and the included angle between the front face S1 and the rear face S2 of the first body portion 13 ranges from 0° to 2°. In this way, the foldable device 10 whose thickness meets a use requirement before and after folding can be obtained.

Referring mainly to FIG. 3, in some implementations, in a state in which the first body portion 13 is folded to overlap the second body portion 14, the first screen portion 12a and the second screen portion 12b overlap each other, and the first bent-screen portion 12d is bent into a water drop shape. In a state in which the third body portion 15 is folded to overlap the folded first body portion 13, the third screen portion overlaps the rear face S2 of the first body portion 13, and the second bent-screen portion 12e is bent into a U shape (also referred to as a baseball shape). In this implementation, based on the wedge-shaped design of the first body portion 13, the second screen portion 12b and the third screen portion 12c need to rotate by a degree less than 180° to change from an unfolded state to a folded state. Compared with a common solution of rotating by 180°, a requirement on folding performance of the flexible display 12 is lowered.

In the state in which the first body portion 13 is folded to overlap the second body portion 14, the first screen portion 12a and the second screen portion 12b are fitted or at a distance less than 1.0 mm, and the first bent-screen portion 12d bent into the water drop shape includes an arc section d3, a first transition section d1, and a second transition section d2. The first transition section d1 is transitionally connected between the arc section d3 and the first screen portion 12a, and the second transition section d2 is transitionally connected between the arc section d3 and the second screen portion 12b.

In a water-drop-shaped bend solution of the flexible display 12, screens have a small distance from each other or are even directly fitted, to reduce a total thickness of a folded structure. However, to realize the water-drop-shaped bend solution, there is a high requirement on thicknesses of body portions (rotatable connection positions of the first body portion 13 and the second body portion 14 in this embodiment) on two sides of a water-drop-shaped bend, and this is inconducive to control of the total thickness existing after folding. In a U-shaped bend solution of the flexible display 12, there is a large distance after folding, and control of the total thickness existing after folding is limited. In this embodiment, the first body portion 13 is arranged in the wedge shape, to skillfully implement a design that a thickness of a side that is of the first body portion 13 and that is close to a water-drop-shaped bend is large (which helps meet a requirement on a thickness of the first body portion 13 at a connection point in the water-drop-shaped bend solution), and a thickness of a side that is of the first body portion 13 and that is close to a U-shaped bend is small (a required distance at the U-shaped bend is reduced, and space within a range of the distance is fully used). A structure is very compact, so that a thickness of the folded foldable device can be greatly reduced compared with that in the conventional technology.

In the water-drop-shaped bend solution in this embodiment, except a shape including the arc section d3, the first transition section d1, and the second transition section d2, a shape including only a single arc (not shown in the figure) may be used, provided that the first bent-screen portion 12d is integrally in a contraction-cavity shape, so that two screen portions (for example, the first screen portion 12a and the second screen portion 12b in this embodiment) connected to the first bent-screen portion 12d can be kept at a small distance (for example, a distance within 1.0 mm) for fitting, even in a position connected to the vicinity of the water-drop-shaped portion. Alternatively, in the water-drop-shaped bend solution, the first bent-screen portion 12d includes both a bending center located on an inner side and a bending center located on an outer side (for example, in this embodiment, a bending center of the arc section is located on an inner side of the water drop shape, and a bending center of connection points between the two transition sections and two corresponding screen portions is located on an outer side of the water drop shape).

In the U-shaped (also referred to as the baseball shape) bend solution, only the bending center located on the inner side exists. Because a bending radius of the flexible display 12 cannot be set to be too small, in a U-shaped connection solution, a distance between two connected screen portions (for example, the second screen portion 12b and the third screen portion 12c in this embodiment) usually cannot be set to be as small as that in the water-drop-shaped connection solution in a position close to a U-shaped opening (for example, the distance ranges from 2.0 mm to 5.0 mm or has a larger value based on a material or performance of the flexible display 12). There are a plurality of solutions for implementing a rotatable connection between adjacent body portions. In this embodiment, the first body portion 13 and the second body portion 14 are rotatably connected by using a first rotation structure 16, and the third body portion 15 and the second body portion 14 are rotatably connected by using a second rotation structure 17. Optionally, the first rotation structure 16 and the second rotation structure 17 each are a hinge structure. The hinge structure usually includes an intermediate portion (not shown in the figure) and side connection portions (not shown in the figure) rotatably connected to two sides of the intermediate portion. Two body portions (for example, the first body portion 13 and the second body portion 14, or the second body portion 14 and the third body portion 15) that need to be rotatably connected are respectively connected to the two side connection portions, and the two body portions can be relatively rotated by using the hinge structure.

The first rotation structure 16, the second rotation structure 17, or the hinge structure applied to a rotatable connection between corresponding body portions in this embodiment may be realized by using another existing transformation structure including a plurality of rotation centers, or using a plurality of connecting rods, or having a same function, provided that the rotatable connection between the corresponding body portions can be implemented, and relative unfolding or folding of the body portions can be implemented. Details are not described herein again.

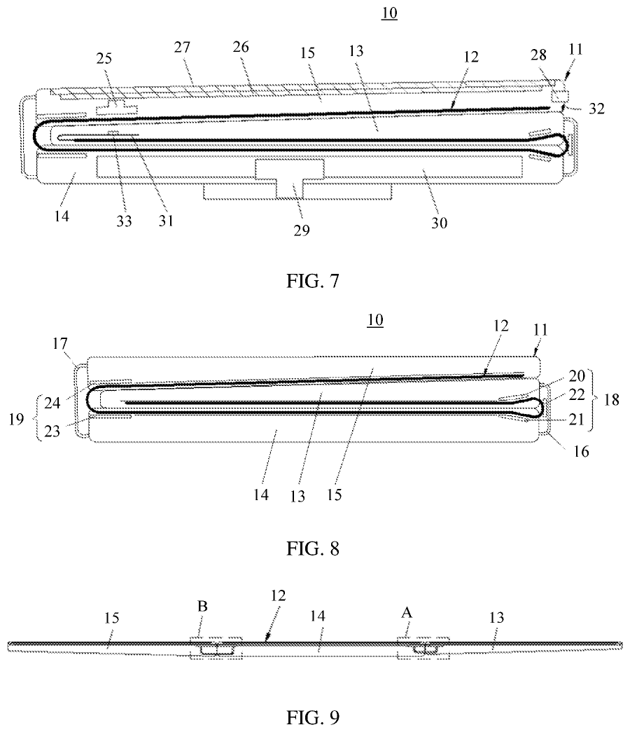

As shown in FIG. 8 to FIG. 11, the foldable device 10 further includes a first support structure 18 and a second support structure 19, the first support structure 18 is configured to support the first bent-screen portion 12d, and the second support structure 19 is configured to support the second bent-screen portion 12e.

Optionally, the first support structure 18 includes a first support plate 20, a second support plate 21, and a third support plate 22. The first support plate 20 is rotatably connected to the first body portion 13, the second support plate 21 is rotatably connected to the second body portion 14, and the third support plate 22 is fixedly connected to the first rotation structure 16. For example, when the first rotation structure 16 is in a form of the hinge structure, the third support plate 22 is fixedly connected to an intermediate portion of the hinge structure, and the first body portion 13 and the second body portion 14 are respectively connected to the two side connection portions. In addition, the first support plate 20 is rotatably connected to the first body portion 13, and the first support plate 20 and a side connection portion on the side implement a transmission connection by using a connecting rod structure (not shown in the figure) or the like. Based on a transmission manner such as a four-connecting-rod mechanism, when the first body portion 13 and the side connection portion rotate by approximately 180° relative to the intermediate portion to be folded from an unfolded state to a folded state, the rotation is transmitted to the first support plate 20 through the connecting rod structure, so that the first support plate 20 rotates by a corresponding angle relative to the first body portion 13, where the angle is, for example, equal to a bending angle of the first transition section d1 (that is, an angle at which the first transition section d1 is bent relative to the first screen portion 12a), to adaptively support the first transition section d1. The second support plate 21 is rotatably connected to the second body portion 14, and the second support plate 21 and a side connection portion on the side implement a transmission connection by using a connecting rod structure (not shown in the figure) or the like. Based on a transmission manner such as a four-connecting-rod mechanism, when the second body portion 14 and the side connection portion rotate by approximately 180° relative to the intermediate portion to be folded from an unfolded state to a folded state, the rotation is transmitted to the second support plate 21 through the connecting rod structure, so that the second support plate 21 rotates by a corresponding angle relative to the second body portion 14, where the angle is, for example, an angle equal to a bending angle of the second transition section d2 (that is, an angle at which the second transition section d2 is bent relative to the second screen portion 12b), to adaptively support the second transition section d2.

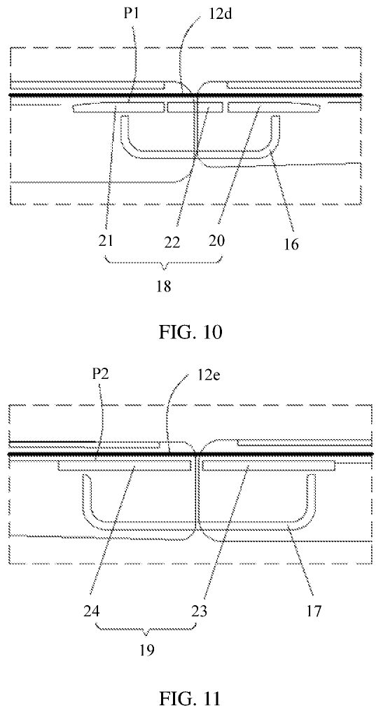

In this arrangement, in a state in which the first body portion 13 and the second body portion 14 are relatively unfolded (referring to FIG. 9 and FIG. 10), the first support plate 20 and the second support plate 21 are respectively located on two sides of the third support plate 22, and support faces P1 of the first support plate 20, the second support plate 21, and the third support plate 22 are on a same plane to jointly support the first bent-screen portion 12d from below. In a state in which the first body portion 13 and the second body portion 14 are folded to overlap each other (referring to FIG. 8), the first bent-screen portion 12d is in a water drop shape, the first support plate 20 rotates to a state of being parallel to the first transition section d1 and supports the first transition section d1 from below, the second support plate 21 rotates to a state of being parallel to the second transition section d2 and supports the second transition section d2 from below, and the third support plate 22 supports the arc section d3 from below.

Referring to FIG. 8 to FIG. 11 again, the second support structure 19 includes a fourth support plate 23 and a fifth support plate 24. The fourth support plate 23 is fixedly connected to a side that is of the second body portion 14 and that is close to the third body portion 15, and the fifth support plate 24 is fixedly connected to a side that is of the third body portion 15 and that is close to the second body portion 14.

In a state in which the third body portion 15 and the second body portion 14 are relatively unfolded (referring to FIG. 9 and FIG. 11), support faces P2 of the fourth support plate 23 and the fifth support plate 24 are on a same plane to jointly support the second bent-screen portion 12e from below.

In a state in which the third body portion 15 and the second body portion 14 are relatively folded into a folded state (referring to FIG. 8), the fourth support plate 23 synchronously rotates along with the second body portion 14 to provide support near a junction of the second screen portion 12b and the second bent-screen portion 12e, and the fifth support plate 24 synchronously rotates along with the third body portion 15 to provide support near a junction of the third screen portion 12c and the second bent-screen portion 12e.

The first support structure 18 and the second support structure 19 are also shown in the implementations shown in FIG. 6 and FIG. 7.

Certainly, in another implementation, the first support structure 18 and the second support structure 19 may alternatively be other support structures: or when the first bent-screen portion 12d and/or the second bent-screen portion 12e do/does not need an additional support, the first support structure 18 and/or the second support structure 19 may not be disposed.

Referring to FIG. 6 and FIG. 7 again, in an implementation, a front-facing camera 25 is disposed on the rear face S2 of the third body portion 15.

As shown in FIG. 6, the front-facing camera 25 penetrates the secondary display 26 disposed on the rear face S2 of the third body portion 15, so that thickness space of the secondary display 26 is used, and a requirement on a thickness of the third body portion 15 is low. In this implementation, a through hole K1 is disposed in the secondary display 26, to accommodate a front end of the front-facing camera 25. In this way, the front-facing camera 25 is shielded by only the protective glass plate 27 and is not shielded by the secondary display 26, and image quality is good.

As shown in FIG. 7, the front-facing camera 25 is located on an inner side of the secondary display 26. In other words, an in-screen camera solution is used. In this solution, a requirement on the thickness of the third body portion 15 is high. This solution may be used in combination with a design in which the included angle between the front face S1 and the rear face S2 of the third body portion 15 is zero or less than the included angle between the front face S1 and the rear face S2 of the first body portion 13. Certainly, in this solution, the front-facing camera 25 is affected by the secondary display 26. This solution may be used regardless of such impact or in combination with another solution that can reduce/eliminate the impact.

Referring to FIG. 6 and FIG. 7 again, in an implementation, the button structure 28 is disposed on the side that is of the third body portion 15 and that is away from the second body portion 14. In a folding manner in this embodiment, the side that is of the third body portion 15 and that is away from the second body portion 14 is exposed without being shielded by a rotation structure (the first rotation structure 16/second rotation structure 17) of a body portion, and it is suitable to dispose the button structure 28 on the side. In addition, as described above, when the front face S1 and the rear face S2 of the third body portion 15 are parallel or the included angle between the front face S1 and the rear face S2 of the third body portion 15 is less than the included angle between the front face S1 and the rear face S2 of the first body portion 13, a thickness of an exposed side of the third body portion 15 is large, and in particular, it is suitable to dispose the button structure 28 on the exposed side. Certainly, when the included angle between the front face S1 and the rear face S2 of the third body portion 15 is equal to the included angle between the front face S1 and the rear face S2 of the first body portion 13, a button structure 28 imposing a low thickness requirement may still be disposed on the exposed side of the third body portion 15.

Referring to FIG. 6 and FIG. 7 again, in an implementation, the foldable device 10 further includes a rear-facing camera 29 and/or a main battery 30 (the main battery 30 is a battery with a largest capacity in the foldable device 10). The rear-facing camera 29 and/or the main battery 30 may be disposed on the second body portion 14. The second body portion 14 is usually arranged as follows: The front face S1 and the rear face S2 are parallel, and the size is regular. In addition, the thickness may be set to be greater than those of the first body portion 13 and the third body portion 15, to help dispose the main battery 30 and a rear-facing camera 29 with a proper size.

Still referring to FIG. 6 and FIG. 7, in an implementation, the foldable device 10 includes a flexible-display lead-out wire 31 and an antenna 32. The flexible-display lead-out wire 31 is used for an electrical connection between the flexible display 12 and a main board of the foldable device 10, and the antenna 32 is used for transmitting and receiving a wireless signal. The flexible-display lead-out wire 31 is led out from a thinner side that is of the flexible display 12 and that corresponds to the first body portion 13, and the antenna 32 is disposed on a side that is of the third body portion 15 and that is away from the second body portion 14.

In a folding solution in this embodiment, the first body portion 13 is sandwiched between the second body portion 14 and the third body portion 15, and it is unsuitable to dispose a folded-state antenna on an edge of the first body portion 13. Therefore, the flexible-display lead-out wire 31 is led out from the edge of the first body portion 13, for example, by using a COP (chip on plastic) bending technology, and a driver chip 33 is disposed on a surface of the flexible-display lead-out wire 31, to reduce panel space that is of a body portion and that is occupied by the flexible-display lead-out wire 31. The side that is of the third body portion 15 and that is away from the second body portion 14 is not shielded, and disposing the antenna 32 on the side is not prone to affecting antenna signal quality.

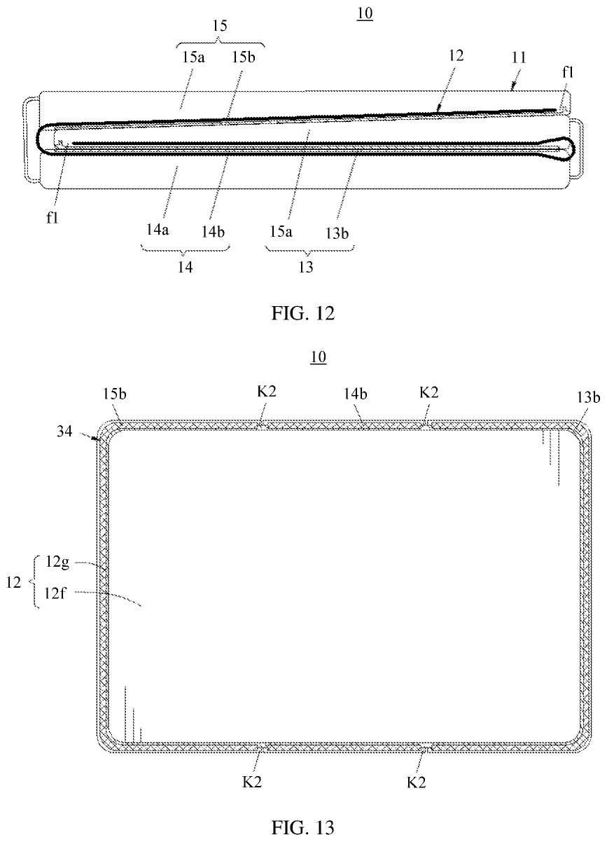

Referring to FIG. 12 and FIG. 13, in an implementation, the first body portion 13 includes a first-body-portion body 13a and a first side housing 13b connected to the first-body-portion body 13a, the second body portion 14 includes a second-body-portion body 14a and a second side housing 14b connected to the second-body-portion body 14a, and the third body portion 15 includes a third-body-portion body 15a and a third side housing 15b connected to the third-body-portion body 15a. The flexible display 12 includes a display area 12f and an outer edge area 12g located on a periphery of the display area 12f. It should be noted that dividing the flexible display 12 into the display area 12f and the outer edge area 12g, or into the first screen portion 12a, the second screen portion 12b, the third screen portion 12c, the first bent-screen portion 12d, and the second bent-screen portion 12e is merely two different division manners of the flexible display 12, and it does not mean that the flexible display 12 separately has the two structures. The flexible display 12 is laid on front faces S1 of the first-body-portion body 13a, the second-body-portion body 14a, and the third-body-portion body 15a. The first side housing 13b, the second side housing 14b, and the third side housing 15b jointly form an outer side-housing frame 34 around a periphery of the body 11. The outer edge area 12g is sandwiched between the outer side-housing frame 34 and each of the first-body-portion body 13a, the second-body-portion body 14a, and the third-body-portion body 15a, and a width-direction gap f1 exists between one or two sides of the outer side-housing frame 34 in the width direction Y1 of the foldable device 10 and a corresponding side of the flexible display 12, to allow the flexible display 12 to displace relative to a width direction the body 11 when the foldable device 10 changes between different folding states. In this implementation, attachment between the flexible display 12 and a corresponding body portion may be arranged as follows: The flexible display 12 is allowed to be misaligned with the body portion to some extent when the flexible display 12 is folded. There are a plurality of attachment methods for achieving such an effect, for example, making adhesive strength of an adhesive layer between the flexible display 12 and each of the first-body-portion body 13a and the second-body-portion body 14a small to allow a specific displacement. In this implementation, in a structural arrangement of a body portion, a displacement existing in the width direction Y1 when the flexible display 12 is bent can be allowed. In addition, the first side housing 13b, the second side housing 14b, and the third side housing 15b protrude from the outer surface of the flexible display 12, and the side housings abut against each other after folding, to prevent the flexible display 12 from being in contact with an opposite-side structure, and reduce a friction and damage possibility.

In an implementation, referring to FIG. 10, a notch K2 is disposed in each of a position that is in the outer side-housing frame 34 and that corresponds to a rotatable connection point between the first body portion 13 and the second body portion 14 and a position that is in the outer side-housing frame 34 and that corresponds to a rotatable connection point between the third body portion 15 and the second body portion 14, so that the first side housing 13b and the third side housing 15b are in U shapes with opposite openings, and separately cover three outer edges of the first-body-portion body 13a and the third-body-portion body 15a. The second side housing 14b includes upper and lower bar-shaped portions, and covers upper and lower edges of the second-body-portion body 14a. Disposing the notch K2 can avoid bending abutment between the first side housing 13b and the second side housing 14b and between the second side housing 14b and the third side housing 15b.

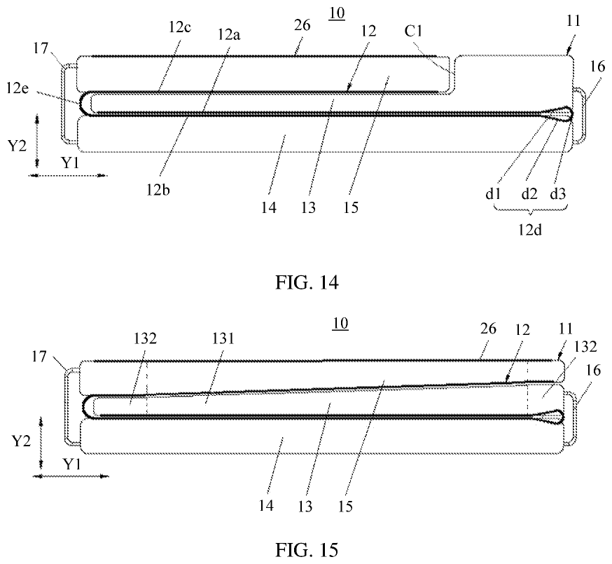

Referring to FIG. 14, an embodiment of this application further provides a foldable device 10. The foldable device 10 is also provided with a structure in which a thickness of a side that is of the first body portion 13 and that is connected to the second body portion 14 is large and a thickness of a side that is of the first body portion 13 and that is away from the second body portion 14 is small. However, the first body portion 13 is not of a wedge-shaped structure but a step-shaped structure. As shown in FIG. 14, a part that is of a rear face of the first body portion 13 and that is located on the side that is of the first body portion 13 and that is away from the second body portion 14 is recessed in a thickness direction of the first body portion 13, to form avoidance space C1, so that the first body portion 13 is in a step shape in which a thickness of a part corresponding to the avoidance space C1 is small and a thickness of a part outside the avoidance space C1 is large. The third body portion 15 is accommodated in the avoidance space C1 when overlapping the first body portion 13. In a folded state, a total thickness of the foldable device 10 is basically determined by a thickness of the second body portion 14, a thickness of the third body portion 15, and a thickness of the thinner portion of the first body portion 13, and the thickness of the thinner portion of the first body portion 13 may be set to be small, to obtain a small overall thickness. Optionally, an outer surface of a portion that protrudes outward from the side that is of the first body portion 13 and that is close to the second body portion 14 may be set to be flush with a rear face of the third body portion 15.

Referring to FIG. 15, an embodiment of this application further provides a foldable device 10. The foldable device 10 is also provided with a structure in which a thickness of a side that is of the first body portion 13 and that is connected to the second body portion 14 is large and a thickness of a side that is of the first body portion 13 and that is away from the second body portion 14 is small. However, the first body portion 13 is not integrally in a wedge shape, but includes a wedge-shaped portion whose thickness gradually changes in a width direction and an equal-thickness portion that has constant thickness and that is connected to one or two sides in a width direction of the wedge-shaped portion. As shown in FIG. 15, the first body portion 13 includes an intermediate wedge-shaped portion 131 and equal-thickness portions 132 respectively disposed on two sides of the wedge-shaped portion 131, an equal-thickness portion 132 on a side close to the second body portion 14 is used to be connected to the second body portion, to help dispose a rotation structure at a water-drop-shaped bend, and an equal-thickness portion 132 on a side away from the second body portion 14 is used to be accommodated on an inner side of a U-shaped bend, to fully use space on the inner side of the U-shaped bend. In another implementation, only one of the two equal-thickness portions 132 may be retained. Optionally, a wedge angle of the wedge-shaped portion ranges from 0.5° to 1.8°.

It can be understood that in another implementation, the first body portion 13 may be in a form other than the form of being integrally in the wedge shape/being partially in the wedge shape/being in a step shape, to achieve a structure in which the thickness of the side connected to the second body portion 14 is large and the thickness of the side away from the second body portion 14 is small.

Based on the foregoing descriptions, in the foldable device 10 in the embodiments of this application, the inward folding manner is used between the first body portion 13 and the second body portion 14 and between the third body portion 15 and the second body portion 14, the thickness of the side that is of the first body portion 13 and that is close to the second body portion 14 is large, and the thickness of the side that is of the first body portion 13 and that is away from the second body portion 14 is small, so that design difficulty of the rotatable connection structure between the first body portion 13 and the second body portion 14 is reduced, and space existing between the second body portion 14 and the third body portion 15 after the second body portion 14 and the third body portion 15 rotate is fully used to help reduce the overall thickness of the foldable device 10. In addition, in the structure, the flexible display 12 is sandwiched between inner sides of the body portions and is difficult to damage, the flexible display 12 only needs to meet the inward folding requirement, and the requirement on performance of the flexible display 12 is low.

The foregoing implementations are merely intended to describe the technical solutions of this application, but not intended to constitute any limitation. Although this application is described in detail with reference to the foregoing preferred implementations, a person of ordinary skill in the art should understand that modifications or equivalent replacements can be made to the technical solutions of this application, without departing from the spirit and scope of the technical solutions of this application.

1. A foldable device, comprising:
a body and a flexible display, wherein
the body comprises a first body portion, a second body portion, and a third body portion that are sequentially disposed, and the first body portion and the third body portion are respectively rotatably connected to two sides in a width direction of the second body portion;
the flexible display comprises a first screen portion, a first bent-screen portion, a second screen portion, a second bent-screen portion, and a third screen portion that are sequentially connected, the first screen portion is attached to a front face of the first body portion, the second screen portion is attached to a front face of the second body portion, and the third screen portion is attached to a front face of the third body portion;
the first body portion is capable of being folded to overlap the second body portion, so that the first screen portion and the second screen portion are opposite to each other and sandwiched between the front face of the first body portion and the front face of the second body portion; and the third body portion is capable of being folded to overlap the folded first body portion, so that the third screen portion is sandwiched between a rear face of the first body portion and the front face of the third body portion; and
a thickness of a side that is of the first body portion and that is connected to the second body portion is large, and a thickness of a side that is of the first body portion and that is away from the second body portion is small.

2. The foldable device according to claim 1, wherein
the first body portion is in a wedge shape whose thickness gradually changes in a width direction.

3. The foldable device according to claim 2, wherein
an included angle between the front face and the rear face of the first body portion ranges from 0.5° to 2°.

4. The foldable device according to claim 2, wherein
the thickness of the side that is of the first body portion and that is connected to the second body portion ranges from 4 mm to 8 mm, the thickness of the side that is of the first body portion and that is away from the second body portion ranges from 2 mm to 5 mm, an included angle between the front face and the rear face of the first body portion ranges from 0.5° to 2°;
a thickness of the second body portion ranges from 4 mm to 8 mm, and the front face and a rear face of the second body portion are parallel to each other; and
a thickness of a side that is of the third body portion and that is connected to the second body portion ranges from 5 mm to 8 mm, a thickness of a side that is of the third body portion and that is away from the second body portion ranges from 2 mm to 8 mm, and an included angle between the front face and a rear face of the third body portion ranges from 0° to 2°.

5. The foldable device according to claim 2, wherein
the third body portion is in a wedge shape whose thickness gradually changes in the width direction, a thickness of a side that is of the third body portion and that is connected to the second body portion is large, and a thickness of a side that is of the third body portion and that is away from the second body portion is small; and
an included angle between the front face and a rear face of the third body portion is equal to an included angle between the front face and the rear face of the first body portion.

6. The foldable device according to claim 2, wherein
the front face and a rear face of the third body portion are parallel.

7. (canceled)

8. The foldable device according to claim 1, wherein
the first body portion comprises a wedge-shaped portion whose thickness gradually changes in a width direction and an equal-thickness portion that has a constant thickness and that is connected to one or two sides in a width direction of the wedge-shaped portion.

9. The foldable device according to claim 1, wherein
in a state in which the first body portion is folded to overlap the second body portion, the first screen portion and the second screen portion overlap each other, and the first bent-screen portion is bent into a water drop shape; and
in a state in which the third body portion is folded to overlap the folded first body portion, the third screen portion overlaps the rear face of the first body portion, and the second bent-screen portion is bent into a U shape.

10. The foldable device according to claim 9, wherein
in the state in which the first body portion is folded to overlap the second body portion, the first screen portion and the second screen portion are fitted or at a distance less than 1.0 mm, the first bent-screen portion bent into the water drop shape comprises an arc section, a first transition section, and a second transition section, the first transition section is transitionally connected between the arc section and the first screen portion, and the second transition section is transitionally connected between the arc section and the second screen portion.

11. The foldable device according to claim 10, wherein
the first body portion and the second body portion are rotatably connected by using a first rotation structure; and
the third body portion and the second body portion are rotatably connected by using a second rotation structure.

12. The foldable device according to claim 11, wherein
the first rotation structure and/or the second rotation structure are/is a hinge structure.

13. The foldable device according to claim 12, wherein
the foldable device further comprises a first support structure and a second support structure, the first support structure is configured to support the first bent-screen portion, and the second support structure is configured to support the second bent-screen portion.

14. The foldable device according to claim 13, wherein
the first support structure comprises a first support plate, a second support plate, and a third support plate;
the first support plate is rotatably connected to the first body portion, the second support plate is rotatably connected to the second body portion, and the third support plate is fixedly connected to the first rotation structure;
in a state in which the first body portion and the second body portion are relatively unfolded, the first support plate and the second support plate are respectively located on two sides of the third support plate, and support faces of the first support plate, the second support plate, and the third support plate are on a same plane to jointly support the first bent-screen portion; and
in a state in which the first body portion and the second body portion are folded to overlap each other, the first bent-screen portion is in the water drop shape, the first support plate rotates to a state of being parallel to the first transition section and supports the first transition section from below, the second support plate rotates to a state of being parallel to the second transition section and supports the second transition section from below, and the third support plate supports the arc section from below.

15. The foldable device according to claim 13, wherein
the second support structure comprises a fourth support plate and a fifth support plate;
the fourth support plate is fixedly connected to a side that is of the second body portion and that is close to the third body portion, and the fifth support plate is fixedly connected to a side that is of the third body portion and that is close to the second body portion;
in a state in which the third body portion and the second body portion are relatively unfolded, support faces of the fourth support plate and the fifth support plate are on a same plane to jointly support the second bent-screen portion; and
in a state in which the third body portion and the second body portion are relatively folded into a folded state, the fourth support plate synchronously rotates along with the second body portion to provide support near a junction of the second screen portion and the second bent-screen portion, and the fifth support plate synchronously rotates along with the third body portion to provide support near a junction of the third screen portion and the second bent-screen portion.

16. The foldable device according to claim 1, wherein
a secondary display is further disposed on a rear face of the third body portion, and a protective glass plate is disposed on an outer side of the secondary display.

17. The foldable device according to claim 16, wherein
a front-facing camera is disposed on the rear face of the third body portion, and the front-facing camera penetrates the secondary display or is located on an inner side of the secondary display.

18. (canceled)

19. The foldable device according to claim 1, wherein
the foldable device comprises a flexible-display lead-out wire and an antenna; and
the flexible-display lead-out wire is led out from a thinner side that is of the flexible display and that corresponds to the first body portion, and the antenna is disposed on a side that is of the third body portion and that is away from the second body portion.

20. The foldable device according to claim 1, wherein
the first body portion comprises a first-body-portion body and a first side housing connected to the first-body-portion body, the second body portion comprises a second-body-portion body and a second side housing connected to the second-body-portion body, the third body portion comprises a third-body-portion body and a third side housing connected to the third-body-portion body, and the flexible display comprises a display area and an outer edge area located on a periphery of the display area;
the flexible display is laid on front faces of the first-body-portion body, the second-body-portion body, and the third-body-portion body; and
the first side housing, the second side housing, and the third side housing jointly form an outer side-housing frame around a periphery of the body, the outer edge area is sandwiched between the outer side-housing frame and each of the first-body-portion body, the second-body-portion body, and the third-body-portion body, and a width-direction gap exists between one or two sides of the outer side-housing frame in a width direction of the foldable device and a corresponding side of the flexible display, to allow the flexible display to displace relative to a width direction of the body when the foldable device changes between different folding states.

21. The foldable device according to claim 20, wherein
a notch is disposed in each of a position that is in the outer side-housing frame and that corresponds to a rotatable connection point between the first body portion and the second body portion and a position that is in the outer side-housing frame and that corresponds to a rotatable connection point between the third body portion and the second body portion.

22. The foldable device according to claim 1, wherein
a part that is of the rear face of the first body portion and that is located on a side that is of the first body portion and that is away from the second body portion is recessed in a thickness direction of the first body portion, to form avoidance space, so that the first body portion is in a step shape in which a thickness of a part corresponding to the avoidance space is small and a thickness of a part outside the avoidance space is large; and
the third body portion is accommodated in the avoidance space when overlapping the first body portion.
